(19) United States
(12) Patent Application Publication
(10) Pub. No.: US 2026/0365185 A1
(43) Pub. Date: Nov. 19, 2026

(54) DEVICE AND METHOD FOR DETECTING ABNORMALITY OF MOTOR, AND COMPUTER-READABLE STORAGE MEDIUM STORING PROGRAM FOR PERFORMING THE METHOD

(71) Applicant: HL MANDO CORPORATION, Gyeonggi-do (KR)

(72) Inventors: Doheon LEE, Gyeonggi-do (KR); Gyuwon KIM, Gyeonggi-do (KR); Jongick WON, Gyeonggi-do (KR)

(21) Appl. No.: 18/637,411

(22) Filed: Apr. 16, 2024

(30) Foreign Application Priority Data
Aug. 9, 2023 (KR) 10-2023-0104199

(51) Int. Cl. B60W 50/02; B62D 5/04

(52) U.S. Cl. CPC B60W 50/0205; B62D 5/0487; B60W 2050/022; B60W 2510/205; B60W 2520/10; B60W 2520/125; B60W 2520/14; B60W 2520/28; B60W 2540/18

(57) ABSTRACT

Disclosed are a device and method, and non-transitory computer-readable storage medium for detecting an abnormality in a motor configured to generate steering assistance torque in an Electric Power Steering (EPS) system. The device includes a memory configured to store an artificial neural network model configured to receive state data related to a state of a vehicle and operation data related to a steering operation of a driver of the vehicle and estimate a physical quantity related to an output of the motor; and a processor configured to input the state data and the operation data into the artificial neural network model, calculate an estimation value of the physical quantity related to the output of the motor, and compare the estimation value with an actual measurement value of the physical quantity to detect the abnormality of the motor.

### CROSS-REFERENCE TO RELATED APPLICATION

This application claims priority to and the benefit of Korean Patent Application No. 10-2023-0104199, filed on Aug. 9, 2023, the disclosure of which is incorporated herein by reference in its entirety.

### TECHNICAL FIELD

The present disclosure generally relates to a device and method for detecting an abnormality of a motor (hereinafter, referred to as a “motor abnormality detection device and method”), and non-transitory computer-readable storage medium storing a program for performing the motor abnormality detection method and more particularly, to a motor abnormality detection device and method for detecting an abnormality of a motor configured to generate steering assist torque in an Electric Power Steering (EPS) system of a vehicle, and a non-transitory computer-readable storage medium storing a program for performing the motor abnormality detection method.

### BACKGROUND

An Electric Power Steering (EPS) system is a device configured to assist in steering a vehicle using a motor. The EPS system analyzes sensed data related to steering wheel operation, vehicle speed, etc. and controls the motor to provide necessary or appropriate steering assist torque. Unlike conventional hydraulic power steering systems, the EPS system can be used in electric vehicles and have higher efficiency in terms of space and fuel.

However, failure of the EPS system while driving, for example, Loss-of-Assist (LoA), may have a significant impact on the vehicle's steering performance and may lead to a fatal accident. The malfunction of the motor that cause steering assist torque is the most important factor of the LoA. Therefore, to ensure the safety of the vehicle, the safety for the failure of the EPS system is required for the motor generating steering torque in the EPS system.

However, conventional approach related to the fail safety of motors in the EPS systems may focus on follow-up measures based on failure rather than preventing failure in advance. Meanwhile, some research and developments are being conducted to early detect defects in EPS motors, but mainly take model-based approaches to simultaneously estimate the state and defects of the system.

### SUMMARY

The present disclosure is to solve the problems as above, and the present disclosure provides a motor abnormality detection device and method, and non-transitory computer-readable storage medium storing program for performing the motor abnormality detection method, thereby predicting malfunction of motor function before a motor failure of an EPS system occurs.

Another object of the present disclosure is to provide a motor abnormality detection device and method, and non-transitory computer-readable storage medium storing a program for performing the motor abnormality detection method, thereby predicting a decrease in an output of a motor based on an artificial intelligence-based digital twin algorithm before Loss-of-Assist (LoA) or a serious decrease in motor torque output occurs in an EPS system.

Still another object of the present disclosure is to provide a motor abnormality detection device and method, and non-transitory computer-readable storage medium storing a program for performing the motor abnormality detection method, thereby predicting a decrease in output of a motor of an EPS system from signals obtained through a Controller Area Network (CAN) of a vehicle.

The objects of the present disclosure are not limited to the above-described objects, and other objects that are not mentioned will be able to be clearly understood by those skilled in the art to which the present disclosure pertains from the following description.

According to an aspect of the present disclosure, there is provided a motor abnormality detection device for detecting an abnormality of a motor that generates a steering assist torque in an electric power steering (EPS) system of a vehicle, the device including a memory, and a processor, wherein the memory stores an artificial neural network model that receives state data related to a state of the vehicle and operation data related to a steering operation of the driver of the vehicle and estimates a physical quantity related to an output of the motor, and the processor inputs the state data and the operation data into the artificial neural network model, performs computations to output an estimation value of the physical quantity, and compares the estimation value with an actual measurement value of the physical quantity to detect whether the motor is abnormal.

In the motor abnormality detection device according to an aspect of the present disclosure, the state data and the operation data may be composed of signals that can be obtained through a controller area network (CAN) of the vehicle.

In the motor abnormality detection device according to an aspect of the present disclosure, the physical quantity may be a steering torque generated when the driver operates a steering wheel of the vehicle.

In the motor abnormality detection device according to an aspect of the present disclosure, the state data may include a longitudinal velocity of the vehicle, a lateral acceleration of the vehicle, a yaw rate of the vehicle, and a wheel velocity of each wheel of the vehicle.

In the motor abnormality detection device according to an aspect of the present disclosure, the operation data may include a steering angle and a steering angular velocity.

In the motor abnormality detection device according to an aspect of the present disclosure, the artificial neural network model may include a generative adversarial network (GAN).

In the motor abnormality detection device according to an aspect of the present disclosure, the artificial neural network model may include a generator that receives the state data and the operation data, and generates the estimation value, and a discriminator that receives actual measurement value-related data including the state data, the operation data, and the actual measurement value, and outputs a discrimination value for the actual measurement value-related data.

In the motor abnormality detection device according to an aspect of the present disclosure, the generator may be configured by a multivariate transformer.

In the motor abnormality detection device according to an aspect of the present disclosure, the discriminator may additionally receive estimation value-related data including the state data, the operation data, and the estimation value, and additionally output a discrimination value for the estimation value-related data.

In the motor abnormality detection device according to an aspect of the present disclosure, the artificial neural network model is constructed by alternately learning the generator and the discriminator, and the state data, the operation data, and the actual measurement value used during the learning may be obtained in a state in which the vehicle and the motor are normal.

In the motor abnormality detection device according to an aspect of the present disclosure, the estimation value may follow the actual measurement value of the physical quantity obtained in a state in which the vehicle and the motor are normal.

In the motor abnormality detection device according to an aspect of the present disclosure, the memory may further store an abnormality detection model, and the processor may determine whether the motor is abnormal by inputting error data related to a difference between the estimation value and the actual measurement value into the abnormality detection model.

In the motor abnormality detection device according to an aspect of the present disclosure, the abnormality detection model may include a One-Class Support Vector Machine (OCSVM) algorithm.

In the motor abnormality detection device according to an aspect of the present disclosure, there may be a plurality of data sets including the state data, the operation data, the actual measurement value, and the estimation value, and the error data includes an average and standard error of the error between the actual measurement value and the estimation value obtained from each of the plurality of data sets, a maximum absolute error between the actual measurement value and the estimation value of the plurality of data sets, and the discrimination value of the discriminator for actual measurement value-related data of the plurality of data sets.

According to another aspect of the present disclosure, there is provided a motor abnormality detection method for detecting an abnormality of a motor that generates a steering assist torque in an electric power steering (EPS) system of a vehicle, the method including receiving, with a processor, state data related to a state of the vehicle, operation data related to a steering operation of a driver of the vehicle, and an actual measurement value of a physical quantity related to an output of the motor, inputting, with the processor, the state data and the operation data into an artificial neural network model, performing computations and outputting an estimation value of the physical quantity, and comparing, by the processor, the estimation value with the actual measurement value to detect whether the motor is abnormal.

In the motor abnormality detection method according to another aspect of the present disclosure, the state data and the operation data may be configured with signals that can be obtained through a Controller Area Network (CAN) of the vehicle.

In the motor abnormality detection method according to another aspect of the present disclosure, the physical quantity may be a steering torque generated when the driver operates a steering wheel of the vehicle.

In the motor abnormality detection method according to another aspect of the present disclosure, the state data may include a longitudinal velocity of the vehicle, a lateral acceleration of the vehicle, a yaw rate of the vehicle, and a wheel velocity of each wheel of the vehicle.

In the motor abnormality detection method according to another aspect of the present disclosure, the operation data may include a steering angle and a steering angular velocity.

In the motor abnormality detection method according to another aspect of the present disclosure, the artificial neural network model may include a Generative Adversarial Network (GAN).

In the motor abnormality detection method according to another aspect of the present disclosure, the artificial neural network model may include a generator that receives the state data and the operation data, and generates the estimation value, and wherein the outputting of the estimation value of the physical quantity may include inputting, with the processor, the state data and the operation data into the generator and outputting the estimation value generated by the generator.

In the motor abnormality detection method according to another aspect of the present disclosure, the artificial neural network model may further include a discriminator that receives actual measurement value-related data including the state data, the operation data, and the actual measurement value, and outputs a discrimination value for the actual measurement value-related data; and wherein the outputting of the estimation value of the physical quantity may include inputting, with the processor, an actual measurement value-related data including the state data, the operation data, and the actual measurement value of the physical quantity into the discriminator, and outputting a discrimination value for the actual measurement value-related data generated by the discriminator.

In the motor abnormality detection method according to another aspect of the present disclosure, the detecting whether the motor is abnormal may include computing, with the processor, error data related to a difference between the estimation value and the actual measurement value and inputting, with the processor, the error data into a one-class support vector machine (OCSVM) algorithm and performing computations.

In the motor abnormality detection method according to another aspect of the present disclosure, there may be a plurality of data sets including the state data, the operation data, the actual measurement value, and the estimation value, and the error data may include an average and standard error of the error between the actual measurement value and the estimation value obtained from each of the plurality of data sets, a maximum absolute error between the actual measurement value and the estimation value of the plurality of data sets, and the discrimination value of the discriminator for actual measurement value-related data of the plurality of data sets.

In the motor abnormality detection method according to another aspect of the present disclosure, the artificial neural network model is constructed by alternately learning the generator and the discriminator, and the state data, the operation data, and the actual measurement value used during the learning may be obtained in a state in which the vehicle and the motor are normal.

According to another aspect of the present disclosure, a non-transitory computer-readable storage medium having a program stored thereon including at least one instruction for performing the motor abnormality detection method.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a block diagram for showing a configuration of a motor abnormality detection device according to an embodiment of the present disclosure.

FIG. 2 is a conceptual diagram schematically showing an electric power steering (EPS) system of a vehicle and state data and operation data according to an embodiment of the present disclosure.

FIG. 3 is a block diagram showing models stored in a memory of a motor abnormality detection device according to an embodiment of the present disclosure.

FIG. 4 is a block diagram showing detailed configuration of an artificial neural network model shown in FIG. 3 according to an embodiment of the present disclosure.

FIG. 5 is a block diagram showing detailed configuration of a generator of the artificial neural network model shown in FIG. 4 according to an embodiment of the present disclosure.

FIG. 6 is a conceptual diagram showing an operation of a motor abnormality detection device according to an embodiment of the present disclosure.

FIG. 7 is a table showing technical effects of a motor abnormality detection device according to an embodiment of the present disclosure.

FIG. 8 is a flowchart of a motor abnormality detection method according to an embodiment of the present disclosure.

FIG. 9 is a flowchart for illustrating a step of outputting an estimation value of a physical quantity in a motor abnormality detection method according to an embodiment of the present disclosure.

FIG. 10 is a flowchart for illustrating a step of detecting whether a motor is abnormal in a motor abnormality detection method according to an embodiment of the present disclosure.

### DETAILED DESCRIPTION

Hereinafter, embodiments of the present disclosure will be described in detail so that those skilled in the art to which the present disclosure pertains can easily carry out the embodiments. The present disclosure may be implemented in many different forms and is not limited to the embodiments described herein. In order to clearly describe the present disclosure, portions not related to the description are omitted from the accompanying drawings, and the same or similar components are denoted by the same reference numerals throughout the specification.

The words and terms used In the specification and the claims are not limitedly construed as their ordinary or dictionary meanings, and should be construed as meaning and concept consistent with the technical spirit of the present disclosure in accordance with the principle that the inventors can define terms and concepts in order to best describe their invention.

In the specification, it should be understood that the terms such as “comprise” or “have” are intended to specify the presence of features, numbers, steps, operations, components, parts, or combinations thereof described in the specification and do not preclude the possibility of the presence or addition of one or more other features, numbers, steps, operations, components, parts, or combinations thereof.

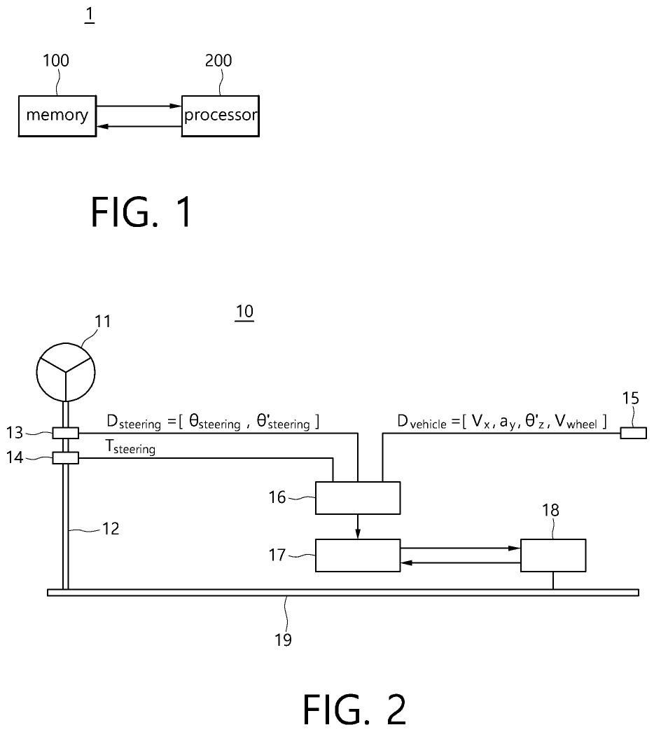

FIG. 1 is a block diagram for showing a configuration of a device for detecting an abnormality of a motor (hereinafter, referred to as a “motor abnormality detection device”) according to an embodiment of the present disclosure.

A motor abnormality detection device 1 according to an embodiment of the present disclosure may be configured to detect an abnormality of a motor configured to generate steering assist torque in an electric power steering (EPS) system of a vehicle. More specifically, the motor abnormality detection device 1 according to an embodiment of the present disclosure may predict the malfunction of the motor before a motor failure occurs through a digital twin algorithm for a vehicle based on artificial intelligence. Specifically, the digital twin algorithm may virtually build the vehicle's EPS system.

According to an embodiment of the present disclosure, the motor abnormality detection device 1 detects the malfunction of the motor before a loss-of-assist (LoA) of the vehicle's EPS system caused by the motor failure occurs. In particular, the motor abnormality detection device 1 according to an embodiment of the present disclosure may sensitively determine even slight performance degradation or deterioration of the motor.

Accordingly, according to an embodiment of the present disclosure, it is possible to predict in advance before the failure of the motor of the EPS system occurs. As a result, it is possible to take precautions before a malfunction of the motor occurs and prevent the motor failure.

Referring to FIG. 1, the motor abnormality detection device 1 according to an embodiment of the present disclosure may include a memory 100 and a processor 200.

The memory 100 may store data, a model, and the like necessary for detecting an abnormality of the motor. For example, the memory 100 may include a hardware device configured to store software or program instructions. For example, the member 100 may be at least one of ROM, RAM, and flash memory. In addition, the memory 100 may include magnetic media such as floppy disks and magnetic tapes, optical media such as compact disk read only memory (CD-ROM), digital video disks (DVD), and magneto-optical media such as floptical disks.

The processor 200 may be configured to input the data into the model and perform computations. For example, the processor 200 may be a hardware unit that can perform computations and control in a computer. The processor 200 may include at least one arithmetic logic unit (ALU) and a register.

The memory 100 stores an artificial neural network model. The artificial neural network model receives state data related to a state of the vehicle and operation data related to a steering operation of the driver of the vehicle and estimates a physical quantity indicating or related to an output of the motor.

The processor 200 inputs the state data and the operation data into the artificial neural network model stored in the memory 100, calculates an estimation value of the physical quantity indicating or associated with the output of the motor, and compares the estimation value with an actual measurement value of the physical quantity to detect whether the motor is abnormal.

In connection with the detection of whether the motor is abnormal, the memory 100 may further store an abnormality detection model. In addition, the processor 200 may determine whether the motor is abnormal by inputting error data related to a difference between the estimation value and the actual measurement value into the abnormality detection model.

FIG. 2 is a conceptual diagram schematically showing an electric power steering (EPS) system of a vehicle and state data and operation data according to an embodiment of the present disclosure. Specifically, FIG. 2 illustrates an EPS system 10 including a motor 18 of which abnormality is to be detected by a motor abnormality detection device 1 according to an embodiment of the present disclosure, and state data (Dvehicle) and operation data (Dsteering).

Referring to FIG. 2, the EPS system 10 of the vehicle may include a steering wheel 11, a steering shaft 12, a steering angle sensor 13, a steering torque sensor 14, and a vehicle state measuring module 15. The steering wheel 11 may be operated by a driver. The steering shaft 12 is connected to the steering wheel 11 to transmit steering force received from the steering wheel 11 to the wheel of the vehicle. The steering angle sensor 13 is disposed on, or adjacent to or in a sensing relationship with, the steering shaft 12 to measure the steering angle and steering angular velocity of the steering wheel 11. The steering torque sensor 14 may be disposed on, or adjacent to or in a sensing relationship with, the steering shaft 12 to measure the steering torque of the steering wheel 11. The vehicle state measuring module 15 may include at least one sensor to measure the state of the vehicle.

For example, the vehicle state measurement module 15 may measure a vehicle's longitudinal velocity (Vₓ), lateral acceleration (a_{y}), yaw rate (θ′_{z}), and wheel velocity (V_{wheel}) of each of the plurality of wheels of the vehicle. Since the vehicle has four wheels in general, four data of the wheel speed (V_{wheel}) for each wheel may be generated by the vehicle state measurement module 15. In other words, the vehicle state measurement module 15 may measure a total of nine types of data regarding the state of the vehicle.

The steering angle (θ_{steering}) and steering angular velocity (θ′_{steering}) measured by the steering angle sensor 13, the steering torque (T_{steering}) measured by the steering torque sensor 14, the vehicle's velocity (Vₓ), the lateral acceleration (a_{y}), the yaw rate (θ′_{z}), and the wheel velocity (V_{wheel}) of each of the plurality of wheels of the vehicle measured by the vehicle state measurement module 15 are transmitted to an electronic control unit (ECU) 17 through a controller area network (CAN) bus 16.

The electronic control unit 17 receives data transmitted through the CAN bus 16, generates a command for controlling the motor 18 generating steering assist torque by processing or computing the received data, and transmits the command to the motor 18 in order to control the motor 18. In this case, the command may be provided to the motor 18 in the form of a current or in a way of supplying a current. The electronic control unit 17 may perform feedback control on the motor 18.

A torque input through the steering wheel 11 by the driver and a torque generated by the motor 18 are transmitted to a steering mechanism 19 connected to one or more vehicle wheels of the vehicle. The direction of the wheels of the vehicle may be changed or adjusted through the steering mechanism 19 driven by the torque input through the steering wheel 11 and the torque generated by the motor 18, thereby performing the steering of the vehicle.

As described above, the memory 100 stores an artificial neural network model configured to receive state data related to a state of the vehicle and operation data related to a steering operation or manipulation of the driver of the vehicle and estimate a physical quantity related to an output of the motor based on the state data and the operation data. the processor 200 inputs the state data and the operation data into the artificial neural network model, performs computations or processes the state data and the operation data to output an estimation value of the physical quantity related to the output of the motor, and compares the estimation value with an actual measurement value of the physical quantity related to the output of the motor in order to detect whether the motor is abnormal. In connection with the detection of whether the motor is abnormal, the memory 100 may further store an abnormality detection model.

In an embodiment of the present disclosure, the state data may include, for example, but not limited to, the vehicle's longitudinal velocity (Vₓ), lateral acceleration (a_{y}), yaw rate (θ′_{z}), and wheel velocity (V_{wheel}) of each of the plurality of wheels of the vehicle. When the vehicle has four wheels in general, the state data may include seven types of data.

In addition, the operation data may include the steering angle (θ_{steering}) and steering angular velocity (θ′_{steering}). As such, the operation data may include two types of data.

As described above, in the motor abnormality detection device 1 according to an embodiment of the present disclosure, the state data and the operation data may be composed of signals obtained through the CAN of the vehicle.

Meanwhile, the physical quantity related to the output of the motor may be a steering wheel torque (T_{steering}) generated when the driver of the vehicle operates the steering wheel 11. In other words, in an embodiment of the present disclosure, the processor 200 may output the estimation value of the steering wheel torque through computations, and compare the estimation value with the actual measurement value of the steering wheel torque to detect whether the motor 18 is abnormal. For instance, the actual measurement value may be the steering torque (T_{steering}) measured by the steering torque sensor 14.

The estimation value of the steering wheel torque may be calculated using, for example, but not limited to, a Dugoff tire model. Since the Dugoff tire model is a well-known model in the automotive engineering field, detailed description will be omitted.

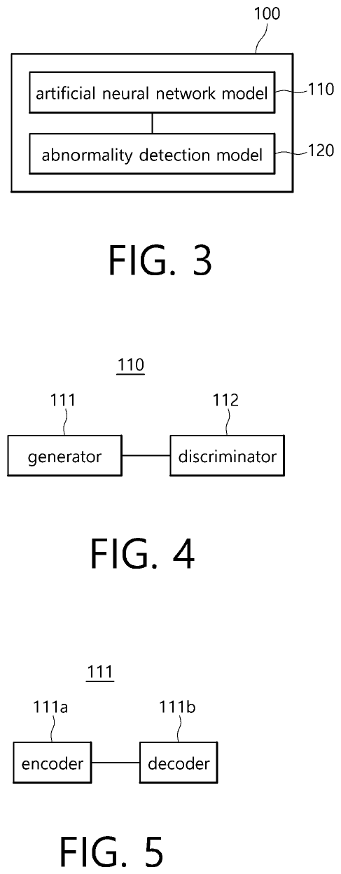

FIG. 3 is a block diagram showing models stored in a memory of a motor abnormality detection device according to an embodiment of the present disclosure. Referring to FIG. 3, the memory 100 may store an artificial neural network model 110 and an abnormality detection model 120.

Hereinafter, the artificial neural network model 110 configured to receive the state data and the operation data and output the estimation value of the steering wheel torque, the abnormality detection model 120 configured to detect whether the motor 18 is abnormal based on comparison between the estimation value of the steering wheel torque and the actual measurement value of the steering wheel torque, and the computations of the processor 200 using the models stored in the memory 100 will be described in detail.

The artificial neural network model 110 receives the state data related to the state of the vehicle and the operation data related to a steering operation or manipulation of the driver of the vehicle, and outputs the estimation value of the steering torque. In an embodiment of the present disclosure, the artificial neural network model 110 may include a generative adversarial network (GAN).

The generative adversarial network is constructed by alternately learning a generator and a discriminator, and the state data related to the state of the vehicle, the operation data related to a steering operation or manipulation of the driver of the vehicle, and the actual measurement value of the steering wheel torque which are used during the learning may be obtained in a state in which the vehicle and the motor 18 are normal. Accordingly, the estimation value of the steering wheel torque may be the same as or substantially identical to the actual measurement value of the physical quantity of the steering wheel torque obtained in a state in which the vehicle and the motor 18 are normal.

In other words, the artificial neural network model 110 may be a virtual twin model virtually duplicated with the EPS system of the vehicle. More specifically, the artificial neural network model 110 may be a deep learning-based neural twin model for the EPS system.

In an embodiment of the present disclosure, the artificial neural network model 110 receives nine types of data including the state of the steering wheel and the vehicle and estimates the steering torque. In this case, the steering torque estimated by the artificial neural network model 110 may reflect a normal operating condition.

FIG. 4 is a block diagram showing detailed configuration of an artificial neural network model shown in FIG. 3 according to an embodiment of the present disclosure. Referring to FIG. 4, the artificial neural network model 110 may include a generator 111 and a discriminator 112.

The generator 111 receives the state data related to the state of the vehicle and the operation data related to a steering operation or manipulation of the driver of the vehicle, and generates the estimation value of the steering wheel torque. The generator 111 may include a neural network. In an embodiment of the present disclosure, the generator 111 may have the virtual twin model virtually duplicated with the EPS system of the vehicle.

For example, the generator 111 may have a multivariate transformer. In other words, the artificial neural network model 110 may be a GAN based on the multivariate transformer.

In an embodiment of the present disclosure, the generator 111 may receive the vehicle's longitudinal velocity (Vₓ), lateral acceleration (a_{y}), yaw rate (θ′_{z}), wheel velocity (V_{wheel}) of each of the plurality of wheels of the vehicle (e.g. four wheel velocities are obtained when the vehicle has four wheels), steering angle (θ_{steering}) and steering angular velocity (θ′_{steering}). In addition, the generator 111 computes or processes the input data and outputs the estimation value of the steering wheel torque.

FIG. 5 is a block diagram showing detailed configuration of a generator of the artificial neural network model shown in FIG. 4 according to an embodiment of the present disclosure. Referring to FIG. 5, the generator 111 may include an encoder 111a and a decoder 111b.

The encoder 111a and the decoder 111b may form a network for estimating the steering torque. In other words, the generator 111 may be composed of an encoder-decoder structural network trained in an end-to-end manner to estimate the steering torque.

The encoder 111a may be configured to extract high-level features from the input data using a transformer block and linear operation. For example, the transformer block may include an embedding layer, a self-attention layer, and a feed-forward layer.

First, the embedding layer in the transformer block may encode spatiotemporal information into input sequences using a trainable embedding matrix.

Next, deep features may be extracted through the self-attention layer of the transformer block and refinement may be performed using the feed-forward layer of the transformer block.

At this time, the self-attention layer may utilize a scaled dot-product attention mechanism. The self-attention layer may be the most important component in the transformer-based deep neural network (DNN) architecture that allows the model to process and understand dependencies in the input sequence.

The scaled dot-product attention may first apply layer normalization to the input sequence and process the results into three unique vectors: query (Q), key (K), and value (V) through linear operation.

Next, an attention score (AS) for each position of the input sequence may be computed based on the derived vectors. The formula for calculating the attention score (AS) may be given as Equation (1) below.

$$AS = σ ( \frac{Q \cdot K}{\sqrt{{‖ {x}_{input} ‖}_{dim}}} ) \cdot V , \qquad Equation ( 1 )$$

wherein σ(·) is softmax computations, ∥xᵢₙₚᵤₜ∥_{dim} is a feature dimension of an input, and (·) means inner product.

The attention score (AS) quantifies the relative importance of each position in the input sequence associated with a given query. That is, higher scores are assigned to more appropriate positions.

The output of the transformer block may be fed to two different linear computations to calculate the queries, key vectors, and initial input values (ŷ₁) of the decoder 111b.

The decoder 111b may estimate the steering torque using the obtained values in an auto-regressive method similar to sequence-to-sequence recurrent neural networks (RNNs).

Similar to the encoder 111a, the decoder 111b may include the transformer block and linear operation. Additionally, the decoder 111b may include a cross-attention layer in the transformer block.

The cross-attention layer may perform the scaled dot-product attention using the queries and key vectors of the encoder 111a to learn dynamic correlations between the input signal and estimated signal, as mentioned above.

The discriminator 112 receives actual measurement value-related data including the state data related to the state of the vehicle, the operation data related to a steering operation or manipulation of the driver of the vehicle, and the actual measurement value of the steering wheel torque, and outputs a discrimination value for the actual measurement value-related data. Additionally, the discriminator 112 may additionally receive estimation value-related data including the state data related to the state of the vehicle, the operation data related to a steering operation or manipulation of the driver of the vehicle, and the estimation value of the steering wheel torque, and may additionally output a discrimination value for the estimation value-related data.

For example, the discriminator 112 may be configured as a discrimination network used for adversarial training of GAN. In other words, the generator 111 and the discriminator 112 may perform training using the adversarial training method to improve estimation performance and set the GAN model. For example, the discriminator 112 may alternately perform optimization with the generator 111 to solve the Wasserstein minimum-max problem using Equation (2).

$${min}_{G} {max}_{D} {E}_{{x}_{D , Real}} [ D ( {x}_{D , Real} ) ] - {E}_{{x}_{D , Fake}} [ D ( {x}_{D , Fake} ) ] , \qquad Equation ( 2 )$$

wherein x_{D,Real} represents actual data set consisting of input data and an actual measurement value of a steering torque, and x_{D,Fake} represents a virtual data sample including input data and the estimation value of the steering torque.

In the artificial neural network model 110, the generator 111 is trained to fake the discriminator 112 that distinguishes the spatiotemporal characteristics of x_{D,Real} and x_{D,Fake}. Accordingly, the generator 111 may generate the estimation value of the steering wheel torque that follows the actual measurement value of the steering torque in the vehicle's EPS system in a steady state.

In this regard, the loss function for GAN training may be defined as shown in Equation (3) below.

$${L}_{G} = \frac{1}{N} \sum \vert {y}_{G} - {\hat{y}}_{G} \vert + 0.001 \times \frac{1}{N} \sum [ - D ( {x}_{D , Fake} ) ] , \qquad Equation ( 3 )$$

$${L}_{D} = \frac{1}{N} \sum [ D ( {x}_{D , Fake} ) - D ( {x}_{D , Real} ) ] + 10 \times \frac{1}{N} \sum [ {( {‖ {∇}_{{x}_{D , Fake}} D ( {x}_{D , Fake} ) ‖}_{2} - 1 )}^{2} ] ,$$

wherein N is batch size, L_{G} is loss function of a generator, and L_{D} is loss function of a discriminator.

The first item of the loss of the generator 111 corresponds to average absolute error loss of map training (LMAE). The remaining item of the loss of the generator 111 forms a GAN loss function (LGAN) along with the loss of discriminator 112.

Meanwhile, a level of degradation of the motor may be predicted based on the estimation value of the physical quantity, indicating or associated with the output of the motor, generated by the generator 111 and the actual measurement value of the physical quantity, indicating or associated with the output of the motor, actually measured.

In an embodiment of the present disclosure, the level of degradation of the motor may be predicted through the abnormality detection model 120.

The abnormality detection model 120 may receive error data related to a difference between the estimation value and the actual measurement value, indicating or associated with the output of the motor, and perform computations or process the received error data. Through the abnormality detection model 120, it may be determined whether the motor 18 is abnormal. In an embodiment of the present disclosure, the abnormality detection model 120 may include a one-class support vector machine (OCSVM) algorithm.

In addition, there are a plurality of data sets including the state data related to the state of the vehicle, the operation data related to a steering operation or manipulation of the driver of the vehicle, the actual measurement value of the steering wheel torque, and the estimation value of the steering wheel torque, and the error data may include an average and standard error between the actual measurement value and the estimation value of the steering wheel torque obtained from each of the plurality of data sets, a maximum absolute error between the actual measurement value and the estimation value of the plurality of data sets, and the discrimination value of the discriminator 112 for actual measurement value-related data of the plurality of data sets.

In other words, a plurality of data sets including the state data related to the state of the vehicle, the operation data related to a steering operation or manipulation of the driver of the vehicle, the actual measurement value of the steering wheel torque, and the estimation value of the steering wheel torque may be treated as one batch. For example, 100 to 150 data sets (e.g., 128 data sets) may be treated or processed as one batch, and the error data may be obtained for each batch.

The error data obtained for one batch may be input to the abnormality detection model 120. In addition, an abnormality level of the motor may be detected based on the output (feature) obtained from the abnormality detection model 120 that receives the error data.

In relation to anomaly detection metric, the F1 score given as shown in Equation (4) below may be considered.

$$F 1 = \frac{2 \times TP}{2 \times TP + FP + FN} , \qquad Equation ( 4 )$$

wherein TP is true positive, FP is false positive, FN is false negative, and positive represents motor degradation.

Meanwhile, the discriminator 112 of the artificial neural network model 110 may calculate not only the discrimination value for the actual measurement value-related data of the data set but also the discrimination value for the estimation value-related data of the data set. The discrimination value of the discriminator 112 for the estimation value-related data of the data set may be fed back to the generator 111 of the artificial neural network model 110 and used for training.

the configuration of the motor abnormality detection device 1 according to an embodiment of the present disclosure has been described above in detail. Hereinafter, the operation of the motor abnormality detection device 1 according to an embodiment of the present disclosure will be described in detail.

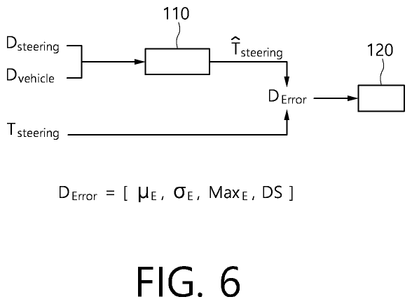

FIG. 6 is a conceptual diagram showing an operation of a motor abnormality detection device according to an embodiment of the present disclosure. Referring to FIG. 6, the motor abnormality detection device 1 according to an embodiment of the present disclosure may operate as follows.

First, the memory 100 stores the state data (D_{vehicle}) related to the state of the vehicle, operation data (D_{steering}) related to a steering operation or manipulation of the driver of the vehicle, and actual measurement value (T_{steering}) of the steering torque obtained from the EPS system of the vehicle. As described above, the state data (D_{vehicle}) may include the vehi'le's longitudinal velocity (Vₓ), lateral acceleration (a_{y}), yaw rate′(θ′_{z}), and wheel velocity (V_{wheel}) of each of the plurality of wheels of the vehicle. In addition, the operation data (D_{steering}) may include the steering angles (θ_{steering}) and steering angular velocities′(θ′_{steering}).

Meanwhile, the plurality of the state data (D_{vehicle}), steering data (D_{steering}), and actual measurement value (T_{steering}) of the steering torque may be treated or processed as one batch. In addition, in an embodiment of the present disclosure, the processing and computation of data may be performed as in an unit of a batch of data.

Next, the processor 200 inputs the state data (D_{vehicle}) related to the state of the vehicle and the operation data (D_{steering}) related to a steering operation or manipulation of the driver of the vehicle into the artificial neural network model 110, performs the computation based on the state data (D_{vehicle}) and the operation data (D_{steering}) to estimate the steering wheel torque, and outputs the estimation value (steering) of the steering wheel torque.

Next, the processor 200 outputs the error data for each data batch. As described above, the error data may include an average and standard error between the actual measurement value and the estimation value obtained from each of the plurality of data sets, a maximum absolute error between the actual measurement value and the estimation value of the plurality of data sets, and the discrimination value of the discriminator 112 for actual measurement value-related data of the plurality of data sets.

Finally, the processor 200 inputs the error data to the abnormality detection model 120 and outputs the result calculated by the abnormality detection model 120. As described above, the abnormality detection model 120 may include, for example, but not limited to, a one-class support vector machine (OCSVM) algorithm. The abnormality level of the motor may be detected based on the output (feature) obtained from the abnormality detection model 120 that receives the error data.

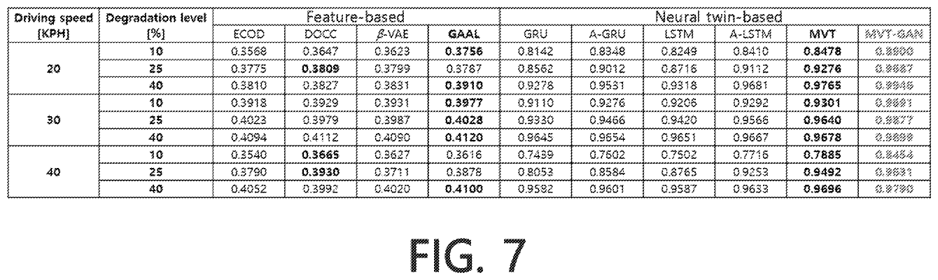

FIG. 7 is a table showing technical effects of a motor abnormality detection device according to an embodiment of the present disclosure.

In FIG. 7, the deterioration level of the motor is predicted through various techniques and models, and an F1 score (anomaly detection metric) is calculated for each technique and model when the speeds of the vehicle are 20 km/h, 30 km/h and 40 km/h and the deterioration levels of the motor of the EPS system of the vehicle are 10%, 25% and 40%, respectively.

In FIG. 7, “feature-based” technique refers to a case in which a neural twin structure is not used, and “Neural twin-based” technique refers to a case in which a deep learning-based neural twin structure is used.

Here, the “feature-based” technique includes an empirical cumulative distribution-based outlier detection (ECOD) algorithm, a deep one-class classification (DOCC) model, a beta-variational autoencoder (β-VAE) model, and a generative adversarial active learning (GAAL).

In addition, the “Neural twin-based” technique includes a gated recurrent unit (GRU) model, a long short-term memory (LSTM) model, their attention base versions (A-GRU, A-LSTM), a simple multivariate transformer (MVT) model without GAN training, and a combination (MVT-GAN) of the artificial neural network model 110 and the abnormality detection model 120 stored in the motor abnormality detection device 1 according to an embodiment of the present disclosure.

Meanwhile, the technique and model shown in FIG. 7 are applied to data acquired from the CAN bus through in-vehicle experiments. For example, the data may be acquired at a sampling rate of 100 Hz.

FIG. 7 may show that the combination (MVT-GAN) of the artificial neural network model 110 and the abnormality detection model 120 stored in the motor anomaly detection device 1 according to an embodiment of the present disclosure shows the highest F1 score in most cases. Specifically, according to one exemplary embodiment of the present disclosure, the performance of an F1 score of 0.85 or more may be predicted up to 10% decrease compared to the maximum output of the motor.

In other words, FIG. 7 may confirm that the motor abnormality detection device 1 according to an embodiment of the present disclosure accurately predicts the level of deterioration of the motor in the vehicle's EPS system before the motor completely fails. In particular, according to an embodiment of the present disclosure, even a slight decrease in output of the motor can be accurately predicted.

In this way, some embodiments of the present disclosure may enable estimation of the future operation and remaining useful life (RUL) of the system and predictive diagnosis suitable for predictive maintenance (PdM) applications. Accordingly, prior action and maintenance may be effectively induced before a failure of the motor of the vehicle's EPS system occurs.

The motor abnormality detection device according to some embodiments of the present disclosure has been described above in detail. Hereinafter, a method for detecting an abnormality of a motor according to an embodiment of the present disclosure will be described.

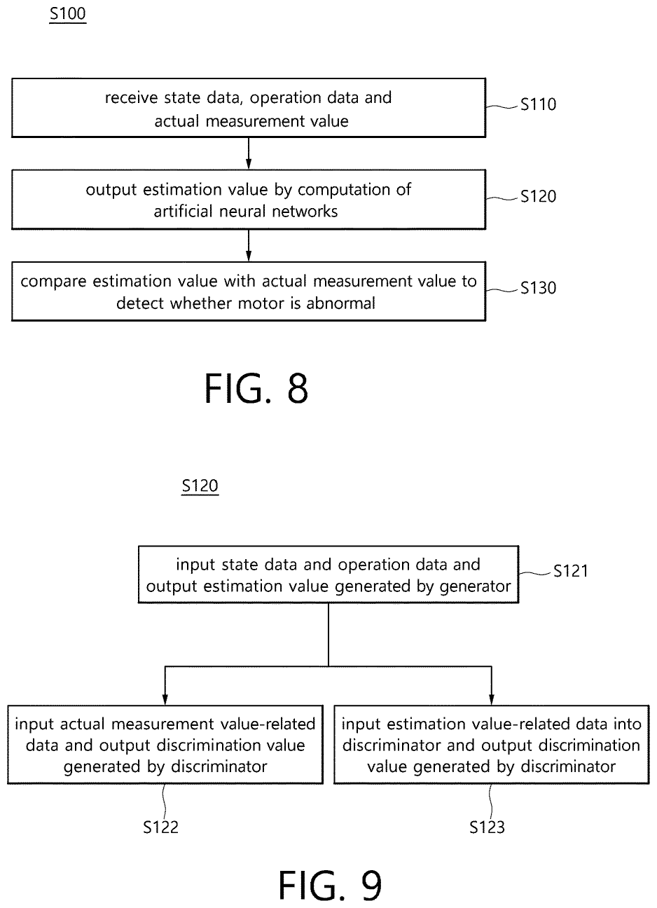

FIG. 8 is a flowchart of a method for detecting an abnormality of a motor (hereinafter, referred to as a “motor abnormality detection method”) according to an embodiment of the present disclosure.

The motor abnormality detection method (S100) according to an embodiment of the present disclosure is a method for detecting abnormality of a motor configured to generate a steering assist torque in an electric power steering (EPS) system of a vehicle, and may be performed by the motor abnormality detection device 1 according to some embodiments of the present disclosure described above.

Referring to FIG. 8, the motor abnormality detection method S100 according to an embodiment of the present disclosure may be performed as follows.

First, the processor 200 receives state data related to a state of the vehicle and operation data related to a steering operation of a driver of the vehicle, and an actual measurement value of a physical quantity related to an output of the motor (step S110).

In an embodiment of the present disclosure, the state data may include a vehicle's longitudinal velocity (Vₓ), lateral acceleration (a_{y}), yaw rate (θ′₂), and wheel velocity (V_{wheel}) of each of the plurality of wheels of the vehicle. As described above, when the vehicle has four wheels, the state data may include seven types of data.

In addition, the operation data may include a steering angle (θ_{steering}) and steering angular velocity (θ′_{steering}). That is, the operation data may include two types of data.

The data listed as examples of the state data and the operation data may be implemented as signals that can be obtained through a controller area network (CAN) of the vehicle. In this way, when the state data and the operation data are implemented in a form of signals obtainable through the controller area network (CAN) of the vehicle, a separate sensor is not required to be arranged in the vehicle to collect data, thereby improving the efficiency of data collection.

In addition, when data transmission to the outside of the vehicle is necessary, the data transmission can be efficiently performed. For example, when the motor abnormality detection device 1 according to an embodiment of the present disclosure is disposed outside the vehicle at a remote location from the vehicle and the motor abnormality detection method according to an embodiment of the present disclosure can performed at the remote location from the vehicle, the state data and the operation data may be efficiently received through telecommunication while the vehicle is driven.

Meanwhile, the physical quantity may be a steering wheel torque (T_{steering}) generated when the driver of the vehicle manipulates or operates the steering wheel 11. In an embodiment of the present disclosure, the processor 200 may output the estimation value of the steering wheel torque through computations, and compare the estimation value with the actual measurement value of the steering wheel torque to detect whether the motor 18 is abnormal. At this time, the actual measurement value may be, for example, but not limited to, the steering torque (T_{steering}) measured by the steering torque sensor 14.

In this case, a plurality of data sets including the state data, the operation data, the actual measurement value, and the estimation value may be processed or treated as one batch. In other words, the processor 200 may receive a plurality of data sets, configure one batch in a unit of a predetermined number, and perform the computations described below in batch units.

Next, the processor 200 inputs the state data and the operation data into the artificial neural network model, performs computations using the artificial neural network model, and outputs an estimation value of the physical quantity (step S120). As described above, the artificial neural network model 110 may include the generative adversarial network (GAN).

The artificial neural network model 110 receives the state data and the operation data, and outputs the estimation value of the steering torque. In an embodiment of the present disclosure, the artificial neural network model 110 may include the generative adversarial network (GAN). In addition, the artificial neural network model 110 may include the generator 111 and the discriminator 112 as described above.

FIG. 9 is a flowchart for illustrating a step of outputting an estimation value of a physical quantity in a motor abnormality detection method according to an embodiment of the present disclosure.

Referring to FIG. 9, step S120 of outputting the estimation value of the physical quantity physicality in the motor abnormality detection method (S100) may be performed as follows.

First, the processor 200 inputs the state data related to the state of the vehicle and the operation data related to a steering operation or manipulation of the driver of the vehicle to the generator 111 and outputs the estimation value of the steering wheel torque generated by the generator 111 (step S121). Here, the generator 111 receives the state data and the operation data to generate the estimation value of the steering wheel torque (step S121).

For example, the generator 111 may be configured as a multivariate transformer. In other words, the artificial neural network model 110 may be a GAN based on a multivariate transformer. In an embodiment of the present disclosure, the generator 111 serves as a virtual twin model virtually duplicated with the EPS system of the vehicle.

The generator 111 may receive the vehicle's longitudinal velocity (Vₓ), lateral acceleration (a_{y}), yaw rate (θ′₂), wheel velocity (V_{wheel}) of each of the plurality of wheels of the vehicle (e.g. four wheel velocities are obtained when the vehicle has four wheels), steering angle (θ_{steering}) and steering angular velocity (θ′_{steering}). In addition, the generator 111 computes the input data and outputs the estimation value of the steering wheel torque.

Next, the processor 200 inputs an actual measurement value-related data including the state data, the operation data, and the actual measurement value of the physical quantity of the steering wheel torque into the discriminator 112, and outputs a discrimination value for the actual measurement value-related data generated by the discriminator 112 is output (step S122).

Meanwhile, the processor 200 inputs an estimation value-related data including the state data related to the state of the vehicle, the operation data related to a steering operation or manipulation of the driver of the vehicle, and the estimation value of the physical quantity of the steering wheel torque into the discriminator 112, and outputs a discrimination value for the estimation value-related data generated by the discriminator 112 (step S123).

In step S122 of outputting the discrimination value for the actual measurement value-related data and step S123 of outputting the discrimination value for the estimation value-related data, the discriminator 112 receives the actual measurement value-related data including the state data, the operation data, and the actual measurement value and outputs the discrimination value for the actual measurement value-related data. The discrimination value for the actual measurement-related data generated by the discriminator 112 may constitute error data input to the abnormality detection model 120, as will be discussed later.

In addition, the discriminator 112 may additionally receive the estimation value-related data including the state data related to the state of the vehicle, the operation data related to a steering operation or manipulation of the driver of the vehicle and the estimation value of the steering wheel torque, and output a discrimination value for the estimation value-related data. The discrimination value for the estimation value-related data generated by the discriminator 112 may be used for training of the generator 111 of the artificial neural network model 110.

Step S122 of outputting the discrimination value for the actual measurement value-related data and step S123 of outputting the discrimination value for the estimation value-related data may be performed at the same time. Alternatively, any one of step S122 of outputting the discrimination value for the actual measurement value-related data and step S123 of outputting the discrimination value for the estimation value-related data may be performed first, and the other one may be performed later.

In the motor abnormality detection method according to an embodiment of the present disclosure, the artificial neural network model 110 may include, for example, but not limited to, a generative adversarial neural network. In this example, the generative adversarial network may be constructed by alternately learning the generator 111 and the discriminator 112, and the state data related to the state of the vehicle, the operation data related to a steering operation or manipulation of the driver of the vehicle, and the actual measurement value of the steering wheel torque used during the learning may be obtained in a state in which the vehicle and the motor are normal.

In other words, the artificial neural network model 110 may be a virtual twin model virtually duplicated with the EPS system of the vehicle. More specifically, the artificial neural network model 110 may be a deep learning-based neural twin model for the EPS system.

In this way, the artificial neural network model 110 receives nine types of data including the state of the steering wheel and the vehicle and estimates the steering torque. In this case, the steering torque estimated by the artificial neural network model 110 may reflect a normal operating condition.

Finally, after step S120 of outputting the estimation value of the physical quantity of the steering wheel torque, the processor 200 compares the estimation value with the actual measurement value of the steering wheel torque to detect whether the motor is abnormal (step S130).

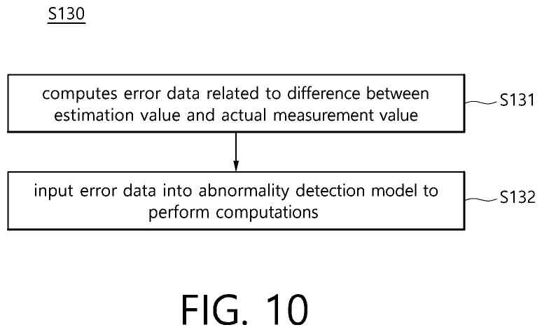

FIG. 10 is a flowchart for illustrating a step of detecting whether a motor is abnormal in a motor abnormality detection method according to an embodiment of the present disclosure.

Referring to FIG. 10, step S130 of detecting whether the motor is abnormal in the motor abnormality detection method (S100) may be performed as follows.

First, the processor 200 computes error data related to a difference between the estimation value and the actual measurement value of the steering wheel torque (step S131).

As described above, there are a plurality of data sets including the state data related to the state of the vehicle, the operation data related to a steering operation or manipulation of the driver of the vehicle, the actual measurement value of the steering wheel torque, and the estimation value of the steering wheel torque, and the error data may include an average and standard error between the actual measurement value and the estimation value obtained of the steering wheel torque from each of the plurality of data sets, a maximum absolute error between the actual measurement value and the estimation value of the plurality of data sets, and the discrimination value of the discriminator 112 for actual measurement value-related data of the plurality of data sets.

The plurality of data sets including the state data, the operation data, the actual measurement value, and the estimation value may be treated or processed as one batch. For example, 100 to 150 data sets (e.g., 128 data sets) may be treated or processed as one batch, and the error data may be obtained for each batch.

Next, the processor 200 inputs the error data into the abnormality detection model 120 to perform computations (step S132). For instance, the abnormality detection model 120 may include a one-class support vector machine (OCSVM) algorithm. In other words, the processor 200 may input the error data into the one-class support vector machine (OCSVM) algorithm to perform computations.

More specifically, the error data obtained for one batch may be input to the abnormality detection model 120. In addition, an abnormality level of the motor may be detected based on the output (feature) obtained from the abnormality detection model 120 that receives the error data.

Meanwhile, some embodiments of the present disclosure may be implemented in a non-transitory computer-readable storage medium having a program stored thereon for performing the motor abnormality detection method. Specifically, a non-transitory computer-readable storage medium having a program stored thereon including at least one instruction for performing the motor abnormality detection method may be provided according to an embodiment of the present disclosure.

At this time, the instruction may include not only machine code generated by a compiler but also high-level language code executable by a computer.

The recording media includes hard disks, magnetic media such as floppy disks, and magnetic tapes, optical media such as Compact Disk Read Only Memory (CD-ROMs), and Digital Video Disks (DVDs), magneto-Optical Media, such as a Floptical Disk, hardware devices configured to store and perform program instructions, such as ROM, RAM, flash memory, etc.

It should be understood that the effects of the present disclosure are not limited to the above-described effects and include all effects inferable from a configuration of the invention described in detailed descriptions or claims of the present disclosure.

Although embodiments of the present disclosure have been described, the spirit of the present disclosure is not limited by the embodiments presented in the specification. Those skilled in the art who understand the spirit of the present disclosure will be able to easily suggest other embodiments by adding, changing, deleting, or adding components within the scope of the same spirit, but this will also be included within the scope of the spirit of the present disclosure.

What is claimed is:

1. A device for detecting an abnormality of a motor configured to generate a steering assist torque in an electric power steering (EPS) system of a vehicle, the device comprising:
a memory configured to store an artificial neural network model configured to receive state data related to a state of the vehicle and operation data related to a steering operation of a driver of the vehicle and estimate a physical quantity related to an output of the motor using the state data and the operation data, and
a processor configured to input the state data related to the state of the vehicle and the operation data related to the steering operation of the driver into the artificial neural network model, calculate an estimation value of the physical quantity related to the output of the motor based on the state data related to the state of the vehicle and the operation data related to the steering operation of the driver using the artificial neural network model, and detect the abnormality of the motor by comparing the estimation value of the physical quantity related to the output of the motor with an actual measurement value of the physical quantity related to the output of the motor.

2. The device of claim 1, wherein the state data and the operation data are comprised in signals received through a controller area network (CAN) of the vehicle.

3. The device of claim 1, wherein the physical quantity related to the output of the motor is a steering torque generated by the driver's operation of a steering wheel of the vehicle.

4. The device of claim 1, wherein the state data related to the state of the vehicle includes:
a longitudinal velocity of the vehicle,
a lateral acceleration of the vehicle,
a yaw rate of the vehicle, and
a wheel velocity of each wheel of the vehicle.

5. The device of claim 1, wherein the operation data related to the steering operation of the driver includes:
a steering angle and
a steering angular velocity.

6. The device of claim 1, wherein the artificial neural network model includes:
a generator configured to receive the state data related to the state of the vehicle and the operation data related to the steering operation of the driver and generate the estimation value of the physical quantity related to the output of the motor; and
a discriminator configured to receive actual measurement value-related data including the state data related to the state of the vehicle, the operation data related to the steering operation of the driver, and the actual measurement value of the physical quantity related to the output of the motor, and output a discrimination value for the actual measurement value-related data.

7. The device of claim 6, wherein the discriminator is configured to receive estimation value-related data including the state data related to the state of the vehicle, the operation data related to the steering operation of the driver, and the estimation value of the physical quantity related to the output of the motor, and output a discrimination value for the estimation value-related data.

8. The device of claim 7, wherein:
the artificial neural network model is constructed by alternately learning the generator and the discriminator, and
the state data, the operation data, and the actual measurement value used during the learning of the generator and the discriminator are obtained in a state in which the vehicle and the motor are normal.

9. The device of claim 8, wherein, in the state in which the vehicle and the motor are normal, the estimation value of the physical quantity related to the output of the motor follows the actual measurement value of the physical quantity related to the output of the motor.

10. The device of claim 6, wherein:
the memory is configured to store an abnormality detection model, and
the processor is configured to detect the abnormality of the motor by inputting error data related to a difference between the estimation value of the physical quantity related to the output of the motor and the actual measurement value related to the output of the motor into the abnormality detection model.

11. The device of claim 10, wherein the error data input to the abnormality detection model includes:
an average and standard error of the difference between the estimation value and the actual measurement value obtained from each of a plurality of data sets including the state data related to the state of the vehicle, the operation data related to the steering operation of the driver, the actual measurement value of the physical quantity related to the output of the motor, and the estimation value of the physical quantity related to the output of the motor,
a maximum absolute error between the actual measurement value and the estimation value of the plurality of data sets, and
the discrimination value of the discriminator for actual measurement value-related data of the plurality of data sets.

12. A method for detecting an abnormality of a motor configured to generate a steering assist torque in an electric power steering (EPS) system of a vehicle, the method comprising:
inputting, by a processor, state data related to a state of the vehicle and operation data related to a steering operation of a driver into an artificial neural network model, and calculating, by the processor, an estimation value of a physical quantity related to an output of the motor using the state data and the operation data; and
detecting, the processor, the abnormality of the motor by comparing the estimation value of the physical quantity related to the output of the motor with an actual measurement value related to the output of the motor.

13. The method of claim 12, wherein the physical quantity related to the output of the motor is a steering torque generated by the driver's operation of a steering wheel of the vehicle.

14. The method of claim 12, wherein the state data related to the state of the vehicle includes:
a longitudinal velocity of the vehicle,
a lateral acceleration of the vehicle,
a yaw rate of the vehicle, and
a wheel velocity of each wheel of the vehicle.

15. The method of claim 12, wherein the operation data related to the steering operation of the driver includes:
a steering angle and
a steering angular velocity.

16. The method of claim 12, wherein the artificial neural network model includes:
a generator configured to receive the state data related to the state of the vehicle and the operation data related to the steering operation of the driver and generate the estimation value of the physical quantity related to the output of the motor; and
wherein the calculating of the estimation value of the physical quantity related to the output of the motor includes inputting, by the processor, the state data related to the state of the vehicle and the operation data related to the steering operation of the driver into the generator and outputting the estimation value generated by the generator.

17. The method of claim 16, wherein the artificial neural network model further includes:
a discriminator configured to receive actual measurement value-related data including the state data related to the state of the vehicle, the operation data related to the steering operation of the driver, and the actual measurement value of the physical quantity related to the output of the motor, and output a discrimination value for the actual measurement value-related data; and
wherein the calculating of the estimation value of the physical quantity related to the output of the motor includes inputting, by the processor, an actual measurement value-related data including the state data related to the state of the vehicle, the operation data related to the steering operation of the driver, and the actual measurement value of the physical quantity related to the output of the motor into the discriminator, and outputting, by the processor, a discrimination value for the actual measurement value-related data generated by the discriminator.

18. The method of claim 17, wherein the detecting of the abnormality of the motor includes:
computing, by the processor, error data related to a difference between the estimation value of the physical quantity related to the output of the motor and the actual measurement value of the physical quantity related to the output of the motor; and
inputting, by the processor, the error data into a one-class support vector machine (OCSVM) algorithm to detect the abnormality of the motor.

19. The motor abnormality detection method of claim 18, wherein the error data input to the one-class support vector machine includes:
an average and standard error of the difference between the estimation value and the actual measurement value obtained from each of a plurality of data sets including the state data related to the state of the vehicle, the operation data related to the steering operation of the driver, the actual measurement value of the physical quantity related to the output of the motor, and the estimation value of the physical quantity related to the output of the motor,
a maximum absolute error between the actual measurement value and the estimation value of the plurality of data sets, and
the discrimination value of the discriminator for actual measurement value-related data of the plurality of data sets.

20. A non-transitory computer-readable storage medium having a program stored thereon including at least one instruction for performing the method of claim 12.
